(19) United States
(12) Patent Application Publication
(10) Pub. No.: US 2010/0091167 A1
(43) Pub. Date: Apr. 15, 2010

(54) SOLID-STATE IMAGE SENSOR AND CAMERA SYSTEM

(75) Inventor: Junichiro Azami, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/574,008

(22) Filed: Oct. 6, 2009

(30) Foreign Application Priority Data
Oct. 9, 2008 (JP) 2008-262974

(51) Int. Cl. H04N 5/225; H01L 27/146; H03F 3/08

(52) U.S. Cl. 348/340; 250/208.1; 250/214 A; 348/E05.024

(57) ABSTRACT

A solid state image sensor includes a pixel unit and a readout unit that reads out per-pixel pixel signals from the pixel unit. The readout unit includes: a plurality of column-parallel comparators that compare a readout signal potential to a reference voltage and output a determination signal; and a plurality of counters that count the comparing time of a corresponding comparator. Each comparator includes: a first amp containing a differential amplifier that receives the reference voltage at the gate of a transistor, receives the readout signal at the gate of another transistor, and compares the reference voltage to the readout signal potential; a second amp containing an amplifier that increases the gain of the first amp's output; and a capacitor connected between the input and the output of the amplifier in the second amp in order to exhibit the Miller effect.

### BACKGROUND OF THE INVENTION

1. Field of the Invention

The present invention relates to a solid-state image sensor as typified by CMOS image sensors, as well as to a camera system.

2. Description of the Related Art

CMOS image sensors have been garnering attention in recent years for use as solid-state image sensors instead of CCDs. Such attention is due to the following reasons. The fabrication of CCD pixels involves specialized processes, and their operation involves a plurality of power supply voltages. Moreover, CCDs are made to operate in conjunction with a plurality of peripheral ICs. In contrast, CMOS image sensors overcome several of the problems related to the significantly increased system complexity in such CCDs.

It is possible for CMOS image sensors to be fabricated using fabrication processes similar to those of typical CMOS integrated circuits. It is also possible to drive CMOS image sensors with a single power supply. Furthermore, CMOS image sensors can be mixed with analog or logical circuits using CMOS processes on the same chip. For these reasons, CMOS image sensors have several significant merits that enable a reduction in the number of peripheral ICs.

Most CCD output circuits yield 1 channel (1ch) output using a floating diffusion (FD) amp having an FD layer. In contrast, most CMOS images sensors have an FD amp for each pixel and yield column-parallel output, wherein a single row is selected from the pixel array, and the values therein are read out simultaneously in column order. Since it is difficult to achieve sufficient driving performance in the FD amps arranged within the pixels, the data rate is decreased, and thus parallel processing is advantageous.

A variety of proposals have been made regarding the signal output circuits of such column-parallel CMOS image sensors.

In one method, a photoelectric transducer such as a photodiode is used to read pixels signals from the CMOS image sensor. Signal charges constituting optical signals generated by the photoelectric transducer are passed through MOS switches disposed nearby, with the subsequent capacitances being briefly sampled and read. In the sampling circuit, there exists noise inversely correlated to the normal sampling capacitance values. Since the signal charges are completely transferred by using the potential gradient when transferring the signal charges to the sampling capacitor, noise is not produced on the sampling order in the pixels. However, there does exist noise when the voltage level of the capacitor from the last sample is reset to a certain reference value.

Correlated double sampling (CDS) is a typical technique for eliminating such noise. With CDS, the state immediately prior to sampling a signal charge (i.e., the reset level) is read and stored. The post-sampling signal level is then read, and noise is eliminated by deducting the reset level from the signal level. There exists a variety of specific CDS techniques.

In addition, a variety of proposals have been made regarding the pixel signal readout (i.e., output) circuits of column-parallel CMOS image sensors. One of the most advanced proposals involves adding an analog-to-digital converter (ADC) to each column, and then taking the pixel signals as digital signals.

Such ADC-equipped column-parallel CMOS image sensors are disclosed in W. Yang et. al, “An Integrated 800×600 CMOS Image System,” ISSCC Digest of Technical Papers, pp. 304-305, February 1999, as well as in Japanese Unexamined Patent Application Publication Nos. 2005-278135, 2005-295346, and S63-209374, for example.

### SUMMARY OF THE INVENTION

As described above, in ADC-equipped column-parallel CMOS image sensors (also referred to as column AD CMOS image sensors), a comparator compares a ramp wave from a DAC to a pixel signal, and AD conversion is conducted by performing digital CDS using a downstream counter.

Typically, the comparator is configured as a two-stage amp, performing a low-speed signal comparison in the initial stage, narrowing the operational band, and then increasing gain in the second-stage amp.

Meanwhile, random noise is an important performance index for solid-state image sensors. The primary sources of random noise are the pixels and the AD converters.

Typical techniques for reducing random noise reducing flicker noise by increasing transistor size, and attempting to filter CDS-induced noise by increasing capacitance in the first-stage comparator output.

However, there are disadvantages to both of the above techniques, in that one entails increased circuit area, while the other entails worsened inversion delay in the comparator due to the increased capacitance, which prevents further increases in the image sensor frame rate.

Although Japanese Unexamined Patent Application Publication Nos. 2005-295346 and S63-209374 make use of the Miller effect in order to reduce reset noise within pixels (i.e., before the vertical signal line), there is a disadvantage in that AD converter noise is not reduced.

It is thus desirable to provide a solid-state image sensor and a camera system wherein frame rate can be improved without increasing circuit area, and able to reduce AD converter noise.

A solid-state image sensor in accordance with a first embodiment of the present invention includes: a pixel unit configured such that a plurality of pixels that conduct photoelectric conversion are disposed in a matrix; and a pixel signal readout unit configured to read out the plurality of pixel signals from the pixel unit on a per-pixel basis. The pixel signal readout unit includes: a plurality of comparators, disposed column-parallel with respect to the pixels, configured to compare a readout signal potential to a reference voltage, and output a determination signal based on the comparison result; and a plurality of counters configured to count the comparing time of a corresponding comparator. Each comparator includes: a first amp containing a differential amplifier configured to receive the reference voltage at the gate of a transistor, receive the readout signal at the gate of another transistor, and compare the reference voltage to the readout signal potential; a second amp containing an amplifier configured to increase the gain of the output of the first amp, and output the result; and a capacitor connected between the input and the output of the amplifier in the second amp in order to exhibit the Miller effect.

A camera system in accordance with a second embodiment of the present invention includes: a solid-state image sensor; and optics configured to focus a subject image onto the image sensor. The solid-state image sensor includes: a pixel unit configured such that a plurality of pixels that conduct photoelectric conversion are disposed in a matrix; and a pixel signal readout unit configured to read out the plurality of pixel signals from the pixel unit on a per-pixel basis. The pixel signal readout unit includes: a plurality of comparators, disposed column-parallel with respect to the pixels, configured to compare a readout signal potential to a reference voltage, and output a determination signal based on the comparison result; and a plurality of counters configured to count the comparing time of a corresponding comparator. Each comparator includes: a first amp containing a differential amplifier configured to receive the reference voltage at the gate of a transistor, receive the readout signal at the gate of another transistor, and compare the reference voltage to the readout signal potential; a second amp containing an amplifier configured to increase the gain of the output of the first amp, and output the result; and a capacitor connected between the input and the output of the amplifier in the second amp in order to exhibit the Miller effect.

According to an embodiment of the present invention, a capacitor exhibits the Miller effect, and thus is equivalent to connecting a gain-multiplied capacitor at the common source input, for example. If the gain of the amplifier is taken to be A_{V2} and the capacitance of the capacitor is taken to be C, then the capacitance seen at the output of the first amp becomes multiplied by the gain according to {C*(1+A_{V2})}. For this reason, the capacitance of the capacitor may be small.

According to an embodiment of the present invention, it is possible to increase frame rate while suppressing increases in circuit area, and AD converter noise can be reduced.

### BRIEF DESCRIPTION OF THE DRAWINGS

FIG. 1 is a block diagram illustrating an exemplary configuration of a column-parallel ADC solid-state image sensor (i.e., CMOS image sensor) in accordance with an embodiment of the present invention;

FIG. 2 is a block diagram illustrating, in further detail, the ADC group in the column-parallel ADC solid-state sensor (i.e., CMOS image sensor) shown in FIG. 1;

FIG. 3 illustrates an example of a CMOS image sensor pixel configured using four transistors in accordance with an embodiment of the present invention;

FIG. 4 is a circuit diagram illustrating an exemplary configuration of a comparator in accordance with an embodiment of the present invention;

FIG. 5 illustrates the operational flow of CDS;

FIG. 6 illustrates the formula of a CDS transfer function;

FIG. 7 illustrates a CDS gain curve with respect to frequency;

FIG. 8 schematically illustrates filtering in CDS;

FIG. 9 illustrates noise reduction using CDS filtering;

FIG. 10 illustrates an example of a comparator for comparison with the circuit shown in FIG. 4;

FIG. 11 illustrates the results of a comparison of inversion delay for an identical cutoff frequency between the circuit of the related art shown in FIG. 10, wherein the Miller effect is not used, and the circuit in accordance with an embodiment of the present invention shown in FIG. 4, wherein the Miller effect is used;

FIG. 12 is a timing chart of the comparator shown in FIG. 4;

FIG. 13A illustrates the inversion delay in the comparator output of the circuit shown in FIG. 10;

FIG. 13B illustrates the inversion delay in the comparator output of the circuit in accordance with an embodiment of the present invention shown in FIG. 4;

FIG. 14 is a circuit diagram illustrating a modification of a comparator in accordance with an embodiment of the present invention; and

FIG. 15 illustrates an exemplary configuration of a camera system to which a solid-state image sensor in accordance with an embodiment of the present invention has been applied.

### DESCRIPTION OF THE PREFERRED EMBODIMENTS

Hereinafter, embodiments of the present invention will be described in conjunction with the accompanying drawings. The description will proceed as follows.

1. Overall exemplary configuration of solid-state image sensor

2. Exemplary configuration of a comparator

3. CDS considerations

4. Comparator operation

5. Modification of comparator

6. Exemplary configuration of a camera system

### <1. Overall Exemplary Configuration of Solid-State Image Sensor>

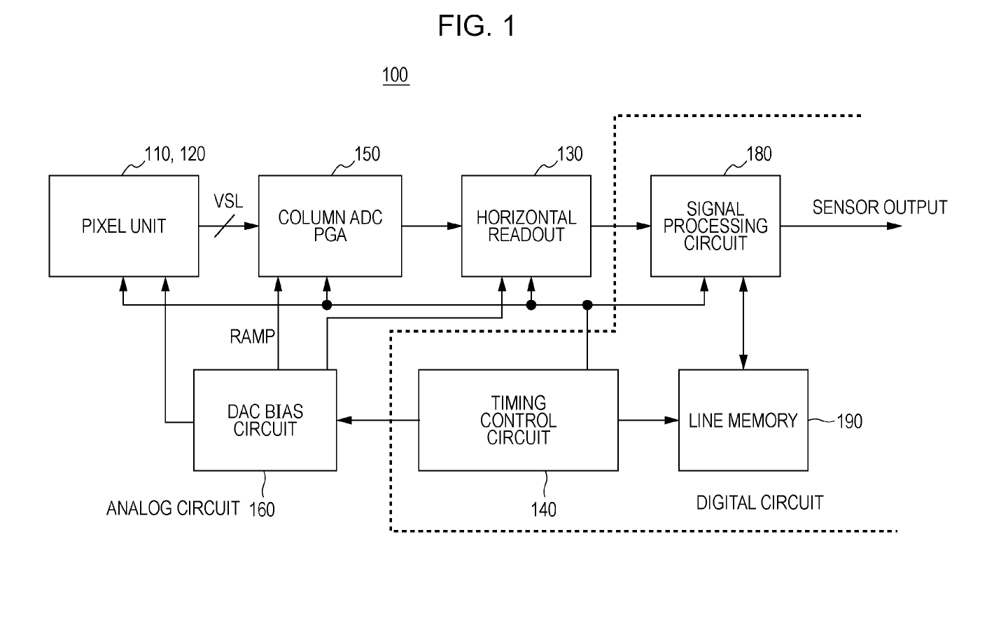

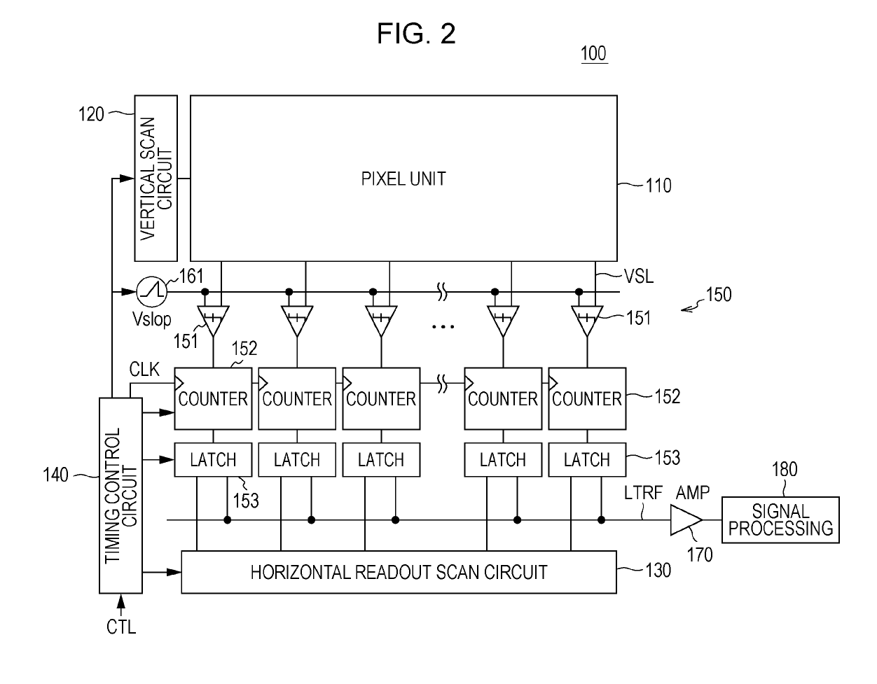

FIG. 1 is a block diagram illustrates an exemplary configuration of a column-parallel ADC solid-state image sensor (i.e., CMOS image sensor) in accordance with an embodiment of the present invention. FIG. 2 is a block diagram illustrating, in further detail, the ADC group in the column-parallel ADC solid-state sensor (i.e., CMOS image sensor) shown in FIG. 1.

As shown in FIGS. 1 and 2, the solid-state image sensor 100 includes a pixel unit 110, a vertical scan circuit 120, a horizontal readout scan circuit 130, and a timing generator circuit 140 that constitute an imaging module, as well as an ADC group 150 that constitutes a pixel signal readout module.

The solid-state image sensor 100 also includes a DAC and bias circuit 160 provided with a digital-to-analog converter (DAC) 161, an amp circuit (S/A) 170, a signal processing circuit 180, and line memory 190.

Among the above components, the pixel unit 110, the vertical scan circuit 120, the horizontal readout scan circuit 130, the ADC group 150, the DAC and bias circuit 160, and the amp circuit (S/A) 170 are realized by analog circuits. Meanwhile, the timing generator circuit 140, the signal processing circuit 180, and the line memory 190 are realized by digital circuits.

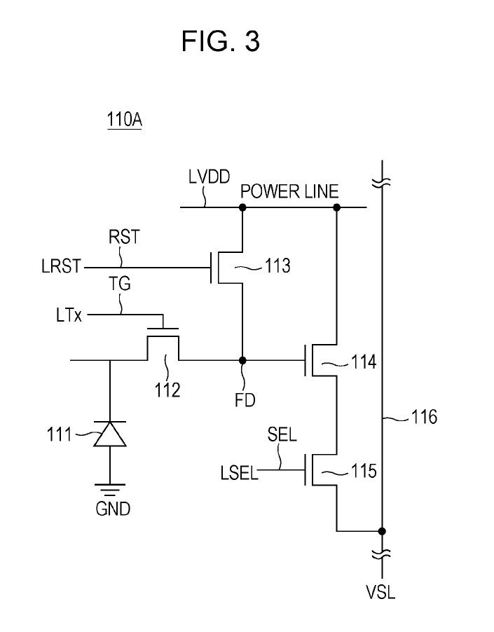

The pixel unit 110 includes photodiodes and in-pixel amps, with the pixels disposed in a matrix as shown in FIG. 3, for example.

FIG. 3 illustrates an example of a CMOS image sensor pixel configured using four transistors in accordance with the present embodiment.

The pixel circuit 110A includes a photoelectric transducer, such as the photodiode 111. In the present example, the pixel circuit 110A includes a single photodiode 111 acting as a photoelectric transducer. The pixel circuit 110A includes four transistors as active elements with respect to the single photodiode 111: a transfer transistor 112 that acts as a transfer element, a reset transistor 113 that acts as a reset element, an amp transistor 114, and a selection transistor 115.

The photodiode 111 photoelectrically converts incident light into a charge (herein, electrons) whose magnitude depends on the amount of light. The transfer transistor 112 is connected between the photodiode 111 and an FD that acts as the output node. By providing the transfer transistor 112 with a drive signal TG at its gate (i.e., the transfer gate) via a transfer control line LTx, the electrons resulting from the photoelectric conversion in the photodiode 111 are transferred to the FD.

The reset transistor 113 is connected between the power supply line LVDD and the FD. By providing the reset transistor 113 with a reset RST at its gate via a reset control line LRST, the electrical potential of the FD is reset to the electrical potential of the power supply LVDD.

The FD is connected to the gate of the amp transistor 114. The amp transistor 114 is connected to a vertical signal line 116 via the selection transistor 115, and forms a constant current source and source follower outside the pixel unit.

A control signal SEL (i.e., an address signal or a select signal) is provided to the gate of the selection transistor 115 via a selection control line LSEL, which activates the selection transistor 115. Once the selection transistor 115 has been activated, the amp transistor 114 amplifies the potential of the FD, and outputs a voltage corresponding to that potential to the vertical signal line 116. The voltages thus output from each pixel via the vertical signal lines 116 are output to the ADC group 150, which acts as a pixel signal readout circuit. Since, for example, the respective gates of the transfer transistor 112, the reset transistor 113, and the selection transistor 115 are connected on a per-row basis, the above operation is conducted simultaneously for all pixels in a single row.

The reset control line LRST, the transfer control line LTx, and the selection control line LSEL that lead to the pixel unit 110 are connected as a set to each row of the pixel array. The reset control line LRST, the transfer control line LTx, and the selection control line LSEL are driven by the vertical scan circuit 120, which acts as a pixel driver.

Also disposed in the solid-state image sensor 100 are: a timing generator circuit 140, which generates an internal clock and acts as a control circuit for successively reading signals from the pixel unit 110; a vertical scan circuit 120, which controls row addressing and row scanning; and a horizontal readout scan circuit 130, which controls column addressing and column scanning.

The timing generator circuit 140 generates timing signals used for signal processing by the pixel unit 110, the vertical scan circuit 120, the horizontal readout scan circuit 130, the ADC group (i.e., the column AGC circuit) 150, the DAC and bias circuit 160, the signal processing circuit 180, and the line memory 190. When row operations are initiated by each comparator in the ADC group, the timing generator circuit 140 generates a control pulse in the form of an auto-zero (AZ) signal applied to an AZ switch in order to determine the working point in each column.

In the pixel unit 110, a video or screen image is photoelectrically converted on a per-pixel-row basis, by means of photonic accumulation and discharge using a line shutter. The resulting analog signal VSL is output to the ADC group.

In each ADC block (i.e., each column unit) of the ADC group 150, the analog output from the pixel unit 110 is subjected to an APGA integrating ADC using a ramp signal RAMP from a DAC 161, as well as digital CDS. A multi-bit digital signal is output.

In the ADC group 150, ADCs are disposed in a plurality of columns. Each ADC includes a comparator 151, which compares a reference voltage Vslop to an analog signal (i.e., a potential VSL). The reference voltage Vslop has a ramp waveform obtained by stepwise variation of a reference voltage generated by the DAC 161. The analog signal (i.e., the potential VSL) is obtained from the pixels on each row line via a vertical signal line.

In addition, each ADC also includes a counter 152 that counts the comparing time, as well as a latch 153 that holds the count result.

The ADC group 150 is configured having functions for n-bit digital signal conversion, with a column-parallel ADC block disposed on each vertical signal line (i.e., each column line). The output of each latch 153 is connected to a horizontal transfer line LTRF of bit width 2n, for example. Additionally, the 2n amp circuit 170 and the signal processing circuit 180 are disposed in correspondence with the horizontal transfer line LTRF. The specific configuration and function of the comparators 151 will be later described.

In the ADC group 150, an analog signal (i.e., the potential VSL) read out onto the vertical signal line 116 is compared to the reference voltage Vslop (i.e., the ramp signal RAMP having a sloped waveform that varies linearly with a given slope) by one of the comparators 151 disposed in each column.

At this point, the counters 152 disposed in each column similarly to the comparators 151 also activate, wherein the counter value is varied in a 1-to-1 relationship with the ramp signal RAMP (i.e., the potential Vslop) having a ramp waveform. In so doing, the potential VSL of the vertical signal line is converted into a digital signal.

The ADCs convert the voltage variation of the reference voltage Vslop (i.e., the ramp signal RAMP) into time variation. By counting this time on a periodic cycle (i.e., clock), the variation is converted into digital values.

When the analog signal VSL and the ramp signal RAMP (i.e., the reference voltage Vslop) intersect, the output of the comparator 151 is inverted, and the input clock of the counter 152 is either suspended, or the suspended clock is input into the counter 152, thereby completing AD conversion.

After the above AD conversion period ends, the data held in the latch 153 is transferred to the horizontal transfer line LTRF by the horizontal readout scan circuit 130, subsequently input into the signal processing circuit 180 via the amp circuit 170, and a two-dimensional image is generated by predetermined signal processing.

In the horizontal readout scan circuit 130, simultaneous parallel transfer on multiple channels is conducted in order to ensure transfer speed. In the timing generator circuit 140, timings are appropriately generated for the signal processing in respective blocks, such as the pixel unit 110 and the ADC group 150. In the downstream signal processing circuit 180, line and point defects are corrected by a signal stored in the line memory 190, the signal is clamped, and other digital signal processing is conducted, such as parallel-serial conversion, compression, encoding, adding, averaging, and intermittent operations. The line memory 190 stores the digital signals transmitted for each pixel row. In the solid-state image sensor 100 of the present embodiment, the digital output of the signal processing circuit 180 is transmitted as the input of an ISP or baseband LSI.

Subsequently, in the ADC group 150 (i.e., the pixel signal readout unit) in accordance with the present embodiment, the Miller effect is used in the amp-based comparators to highly constrain the passband in order to reduce pixel and comparator noise. Each comparator 151 in the present embodiment is configured as follows.

### <2. Exemplary Configuration of a Comparator>

Each of the comparators 151 disposed in each column includes cascading first and second amps. Furthermore, the second-stage second amp is a common source amplifier with a capacitor connected between its input and output nodes. This capacitor exhibits the Miller effect, and is equivalent to connecting a gain-multiplied capacitor at the common source input. As a result, the passband of each comparator 151 can be significantly narrowed using a small capacitor. Each comparator 151 also includes functions for auto-zero (AZ) and sampling in order to determine the working point in each column when initiating row operations.

Hereinafter, the configuration and function of the comparators 151 in the ADC group 150 (i.e., the pixel signal readout unit) having the characteristic configuration of the present embodiment will be described in detail. In the present embodiment, the first conductivity type may be p-channel or n-channel, while the second conductivity type may be n-channel or p-channel. The comparator described hereinafter has been given the reference label 200.

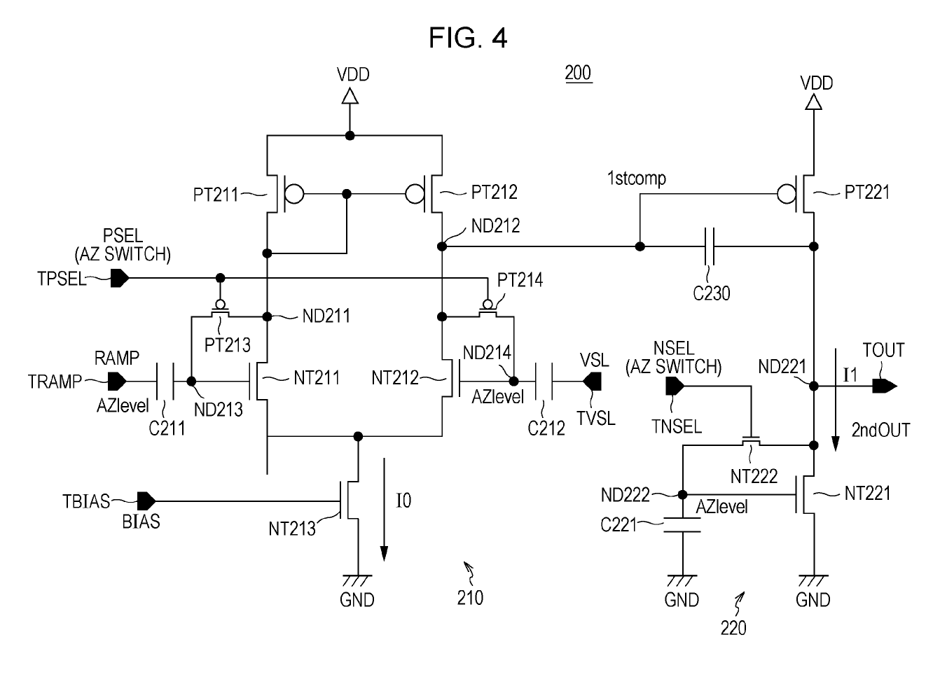

FIG. 4 is a circuit diagram illustrating an exemplary configuration of a comparator in accordance with the present embodiment. As shown in FIG. 4, the comparator 200 includes a cascading first amp 210 and second amp 220, as well as a capacitor C230 for exhibiting the Miller effect.

The first amp 210 includes p-channel MOS (PMOS) transistors PT211 to PT214, n-channel MOS (NMOS) transistors NT211 to NT213, as well as first and second capacitors C211 and C212, which act as AZ level sampling capacitors.

The source of the PMOS transistor PT211 and the source of the PMOS transistor PT212 are connected to a power supply potential source VDD. The drain of the PMOS transistor PT211 is connected to the drain of the NMOS transistor NT211, with the connection point forming a node ND211. In addition, the drain and gate of the PMOS transistor PT211 are connected, and the connection point is connected to the gate of the PMOS transistor PT212. The drain of the PMOS transistor PT212 is connected to the drain of the NMOS transistor NT212, with the connection point forming the output node ND212 of the first amp 210. The sources of the NMOS transistor NT211 and the NMOS transistor NT212 are connected, and the connection point is connected to the drain of the NMOS transistor NT213. The source of the NMOS transistor NT213 is connected to a reference potential source GND (ground potential, for example).

The gate of the NMOS transistor NT211 is connected to the first electrode of the capacitor C211, with the connection point forming a node ND213. In addition, the second electrode of the capacitor C211 is connected to an input terminal TRAMP for receiving the ramp signal RAMP. The gate of the NMOS transistor NT212 is connected to the first electrode of the capacitor C212, with the connection point forming a node ND214. In addition, the second electrode of the capacitor C212 is connected to an input terminal TVSL for receiving the analog signal VSL.

Meanwhile, the gate of the NMOS transistor NT213 is connected to an input terminal TBIAS for receiving a bias signal BIAS. The source of the PMOS transistor PT213 is connected to the node ND211, while the drain is connected to the node ND213. The source of the PMOS transistor PT214 is connected to the node ND212, while the drain is connected to the node ND214. Additionally, the gates of the PMOS transistors PT213 and PT214 are both connected to an input terminal TPSEL for receiving a first AZ signal PSEL active at low level.

In the first amp 210 having the above configuration, a current mirror circuit is realized by the PMOS transistors PT211 and PT212, while a differential comparator is realized by the NMOS transistors NT211 and NT212, using the NMOS transistor NT213 as a current source. Furthermore, the PMOS transistors PT213 and PT214 function as AZ switches, while the capacitors C211 and C212 function as AZ level sampling capacitors. The output signal 1stcomp from the first amp 210 is output from the output node ND212 to the second amp 220.

The second amp 220 includes a PMOS transistor PT221, NMOS transistors NT221 and NT222, as well as a third capacitor C221 that acts as an AZ level sampling capacitor.

The source of the PMOS transistor PT221 is connected to a power supply potential VDD, while the gate is connected to the output node ND212 of the first amp 210. The drain of the PMOS transistor PT221 is connected to the drain of the NMOS transistor NT221, with the connection point forming an output node ND221. The source of the NMOS transistor NT221 is connected to the ground potential GND, while the gate is connected to the first electrode of the capacitor C221, with the connection point forming a node ND222. The second electrode of the capacitor C221 is connected to the ground potential GND. The drain of the NMOS transistor NT222 is connected to the output node ND221, while the source is connected to the node ND222. In addition, the gate of the NMOS transistor NT222 is connected to an input terminal TNSEL for receiving a second AZ signal NSEL active at high level. The second AZ signal NSEL takes a level complementary with that of the first AZ signal PSEL supplied to the first amp 210.

In the second amp 220 having the above configuration, an input and amplification circuit is realized by the PMOS transistor PT221. In addition, the NMOS transistor NT222 functions as an AZ switch, while the capacitor C221 functions as an AZ level sampling capacitor. The output node ND221 of the second amp 220 is connected to the output terminal TOUT of the comparator 200.

The first electrode of the capacitor C230 is connected to the gate (i.e., the input) of the PMOS transistor PT221 that acts as the common-source amplifier, while the second electrode is connected to the drain (i.e., the output) of the PMOS transistor PT221. The capacitor C230 thus exhibits the Miller effect, and is equivalent to connecting a gain-multiplied capacitor at the common source input.

If the gain of the PMOS transistor PT221 is taken to be A_{V2} and the capacitance of the capacitor C230 is taken to be C, then the capacitance seen at the output of the first amp 210 becomes multiplied by the gain according to {C*(1+A_{V2})}. For this reason, the capacitance of the capacitor C230 may be small. As a result, the passband of the comparator 200 can be significantly narrowed using a small capacitor.

### <3. CDS Considerations>

Correlated double sampling (CDS) performed using an ADC containing the comparator 200 (151) configured as above will now be considered.

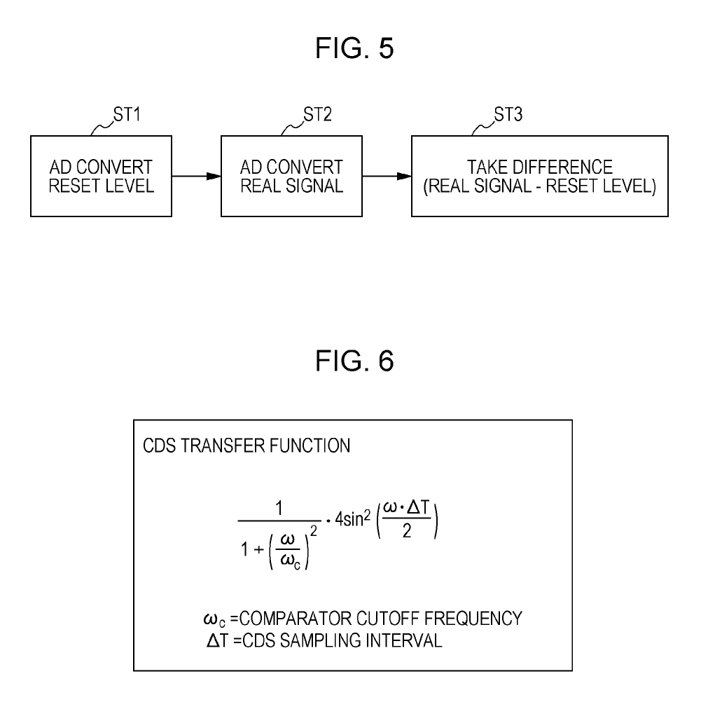

FIG. 5 illustrates the operational flow of CDS. As shown in FIG. 5, CDS involves first AD converting the pixel reset level (ST1), AD converting the real signal (ST2), and then taking the difference therebetween as the final data (ST3).

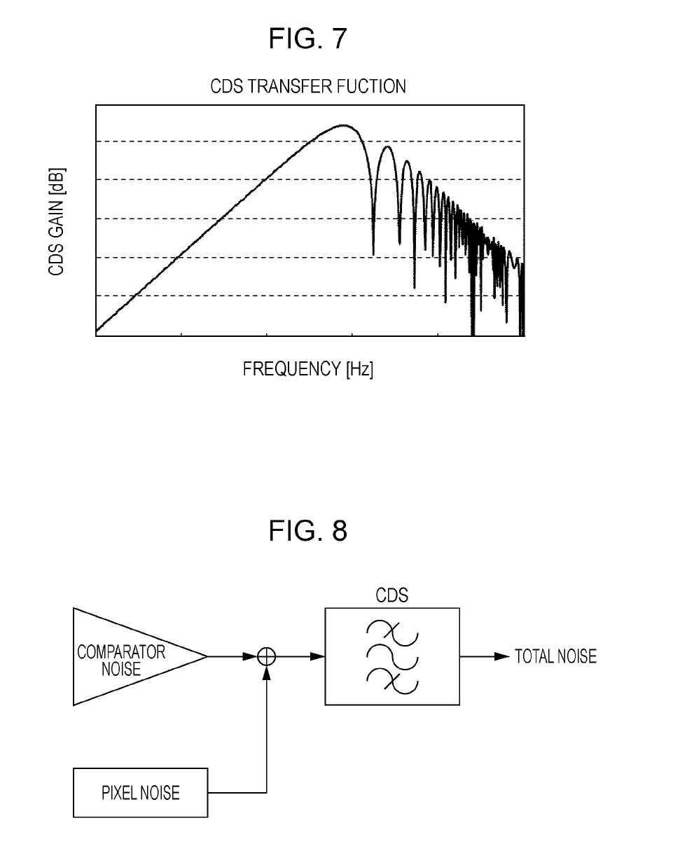

FIGS. 6 and 7 illustrate the CDS transfer function. FIG. 6 shows the formula for the CDS transfer function, while FIG. 7 illustrates a CDS gain curve plotted with respect to frequency. Additionally, FIG. 8 schematically illustrates CDS-based filtering.

As shown in FIGS. 6 and 7, CDS refers to a bandpass transfer curve. Additionally, as shown in FIG. 8, pixel noise as well as noise from the comparator itself are filtered by CDS. In other words, because of the Miller effect, overall noise in a solid state image sensor decreases due to the CDS transfer curve as the cutoff frequency ω_{C} of the comparator is lowered.

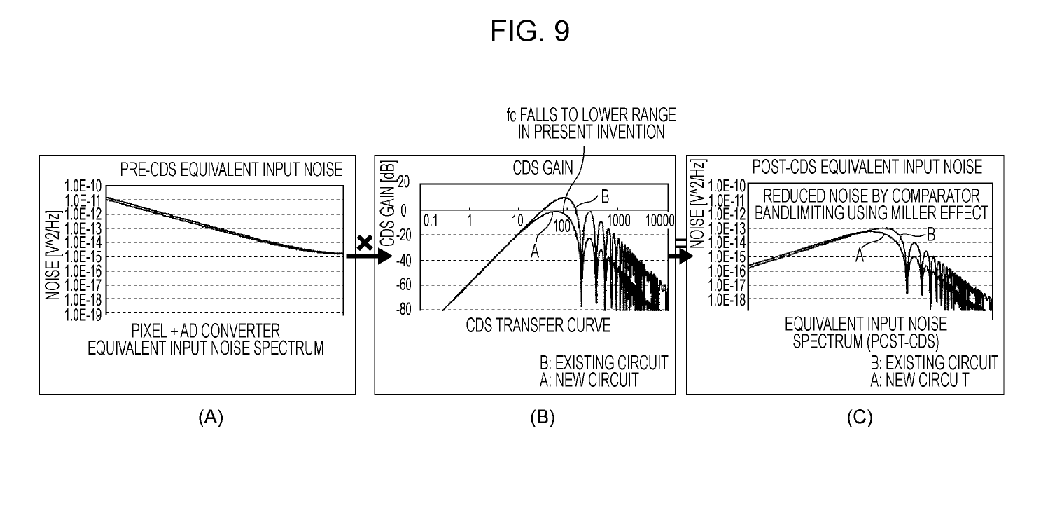

FIG. 9 illustrates noise reduction using CDS filtering. The left part of FIG. 9 illustrates pre-CDS equivalent input noise, the middle part illustrates CDS gain, and the right part illustrates post-CDS equivalent input noise. In the middle and right parts, the curve A illustrates the characteristics of a circuit in accordance with an embodiment of the present invention, while the curve B illustrates the characteristics of a circuit of the related art.

The post-CDS noise spectrum is the spectrum obtained by applying the CDS transfer curve to the combined noise from both the pixels and the AD converter (ADC). The right part of FIG. 9 demonstrates that the noise spectrum level is lowered as a result of constraining the passband in the comparator using the Miller effect.

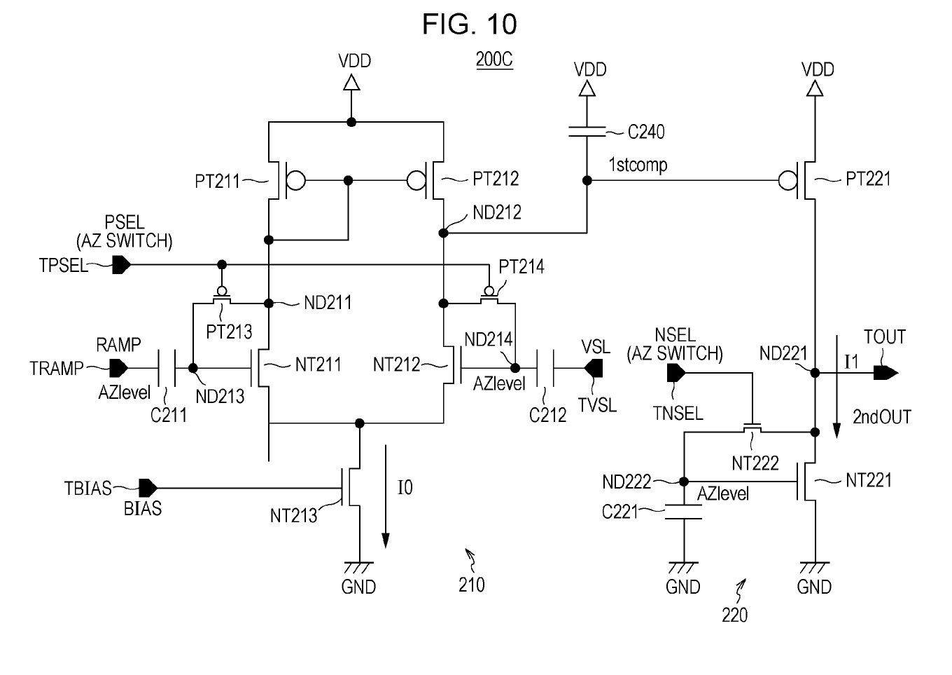

FIG. 10 illustrates a comparator for comparison with the circuit shown in FIG. 4. In the comparator 200C shown in FIG. 10, a capacitor C240 is connected to the output of a first-stage first amp 210 (i.e., a differential amplifier). As a result, it is possible to constrain the passband without the use of the Miller effect.

However, when the passband is to be highly constrained in the comparator 200C, the size of the capacitor becomes very large. The discharge time with respect to the capacitor thus becomes time-consuming, which worsens the frame rate and increases the inversion delay of the comparator itself.

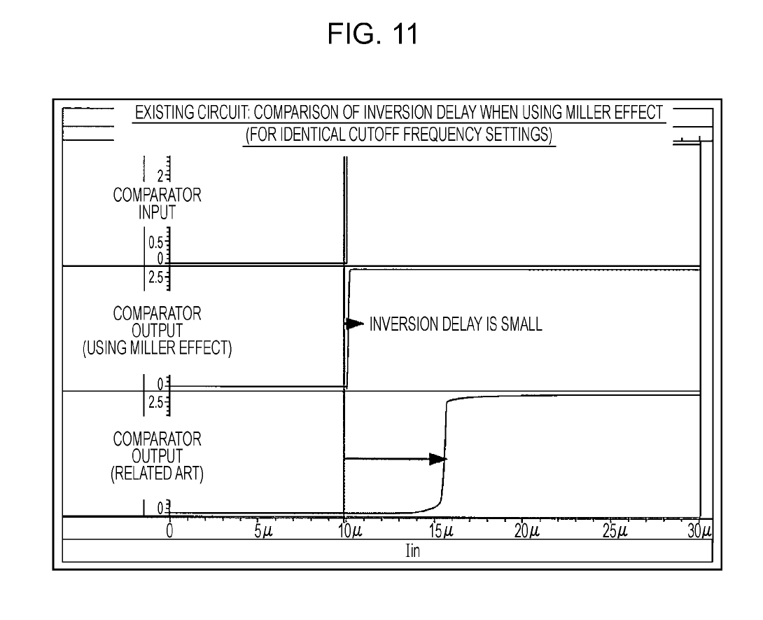

FIG. 11 illustrates the results of a comparison of inversion delay for an identical cutoff frequency between the circuit of the related art shown in FIG. 10, wherein the Miller effect is not used, and the circuit in accordance with an embodiment of the present invention shown in FIG. 4, wherein the Miller effect is used. As shown in FIG. 11, the circuit in accordance with an embodiment of the present invention has a smaller inversion delay compared to that of the circuit of the related art. If the inversion delay of the comparator is increased, the AD conversion time also increases, ultimately leading a reduction in the frame rate.

Thus, in the comparator 200 in accordance with the present embodiment, the passband is constrained using the Miller effect, thereby reducing random noise without decreasing the frame rate. Moreover, since the above is achieved using a small capacitor, the present embodiment is also advantageous from the standpoints of circuit area and cost.

### <4. Comparator Operation>

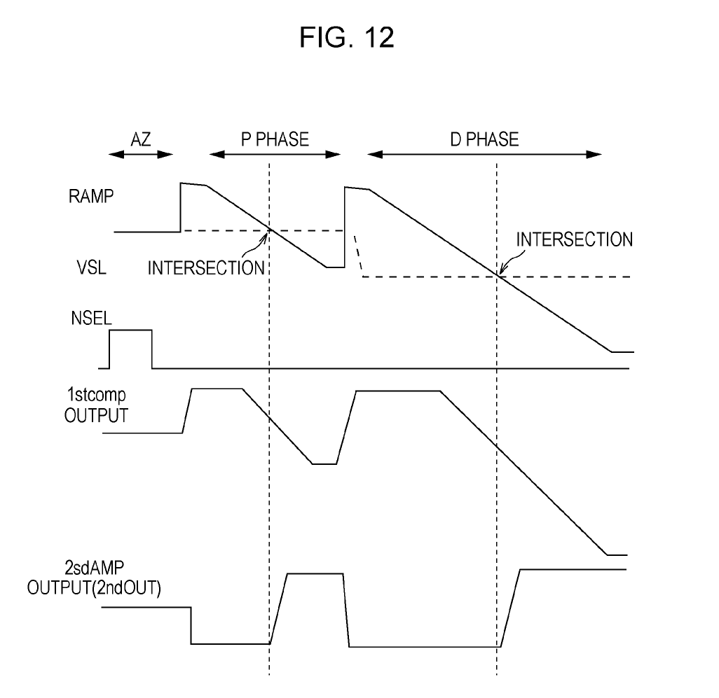

The operation of the comparator 200 in accordance with the present embodiment will now be described in association with the timing chart shown in FIG. 12. It should be appreciated that the AZ signal shown in FIG. 12 is only the second AZ signal NSEL supplied to the second amp 220. As described earlier, the first AZ signal PSEL takes a level complementary with that of the second AZ signal NSEL. In other words, the first AZ signal PSEL is low when the second AZ signal NSEL is high, and likewise, the first AZ signal PSEL is high when the second AZ signal NSEL is low.

In the comparator 200, a low first AZ signal PSEL and a high second AZ signal NSEL are supplied during the AZ period. As result, the PMOS transistors PT213 and PT214, which act as the AZ switches of the first amp 210, are switched on. Similarly, the NMOS transistor NT222, which acts as the AZ switch of the second amp 220, is also switched on.

Thus, in the ADC group 150, the plurality of comparators 200 are used to sample the DAC offset levels, the pixel reset levels, and the per-column AZ levels, and charge is accumulated in the AZ level sampling capacitors C211, C212, and C221.

When the AZ period ends, the first AZ signal PSEL is switched high, while the second AZ signal NSEL is switched low. As a result, the PMOS transistors PT213 and PT214, which act as the AZ switches of the first amp 210, are switched off. Similarly, the NMOS transistor NT222, which acts as the AZ switch of the second amp 220, is also switched off. In so doing, integrating AD conversion of the pixel reset level (hereinafter referred to as the P phase) is initiated.

In the P phase, nodes ND213 and ND214 (formed between the sampling capacitors C211 and C212 that were charged during the AZ period, and the NMOS transistors NT211 and NT212) in the first amp 210 of the comparator 200 become high impedance (HiZ) nodes. For this reason, the gate inputs of the differential NMOS transistors NT211 and NT212 vary according to the ramped variation in the ramp signal RAMP from the DAC 161, and comparison with the VSL level (i.e., the pixel signal) is initiated.

Once the ramp signal RAMP and the pixel signal intersect, the output signal 1stcomp of the first amp 210 changes sharply. As a result, the PMOS transistor PT221 of the second amp 220 is switched on, a current I1 begins to flow, and the output 2ndOUT of the second amp 220 changes from low (L) to high (H).

Similarly, in the D phase, the per-column comparators 200 operate in the same way as in the P phase. Thus, kTC noise and pixel reset noise can be canceled out as a result of digital CDS (see the D phase period in the timing chart shown in FIG. 12).

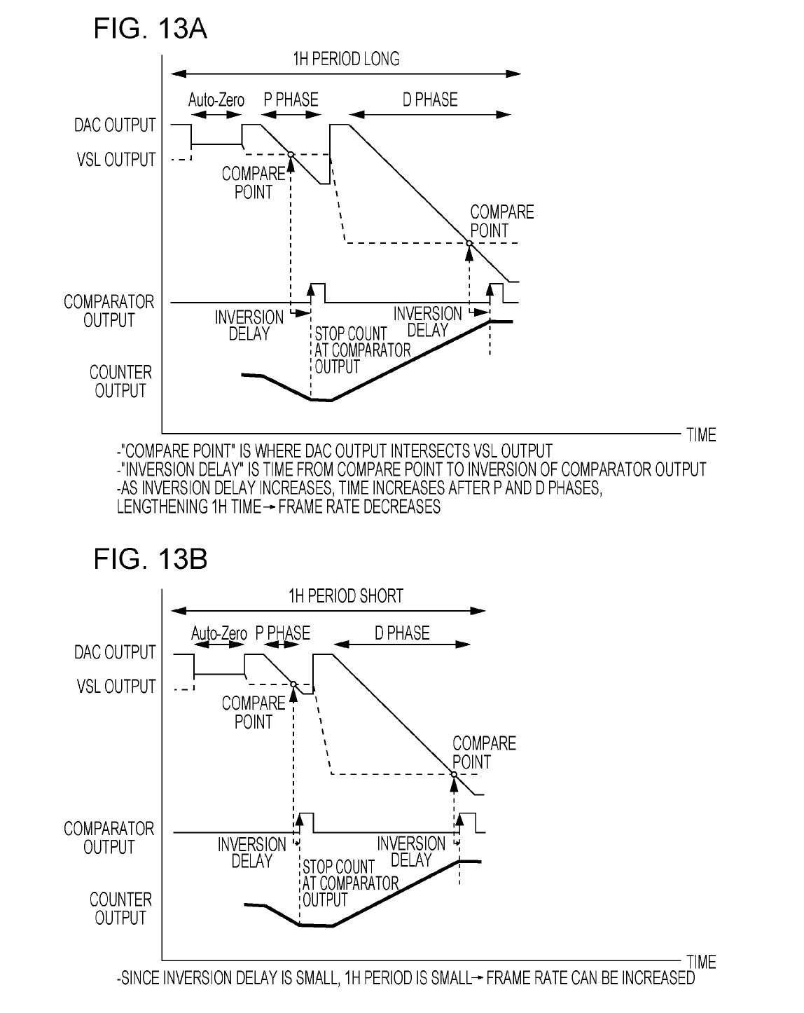

FIGS. 13A and 13B compare the inversion delay in the comparator output of a circuit in accordance with an embodiment of the present invention versus a circuit of the related art. FIG. 13A illustrates comparator output in the circuit of the related art shown in FIG. 10, while FIG. 13B illustrates comparator output in the circuit in accordance with an embodiment of the present invention shown in FIG. 4.

FIG. 13A illustrates a timing chart for the case when the passband is constrained according to a technique of the related art. As shown in FIG. 13A, when the inversion delay is large, the amount of time spent in the P and D phases is increased, which results in a reduced frame rate.

FIG. 13B illustrates the case when the passband is constrained using the circuit in accordance with the present embodiment shown in FIG. 4. In the case of FIG. 13B, the P and D phases are shorter compared to those shown in FIG. 13A. The 1H timing is thus also shorter, and as a result, the frame rate can be increased.

### <5. Modification of Comparator>

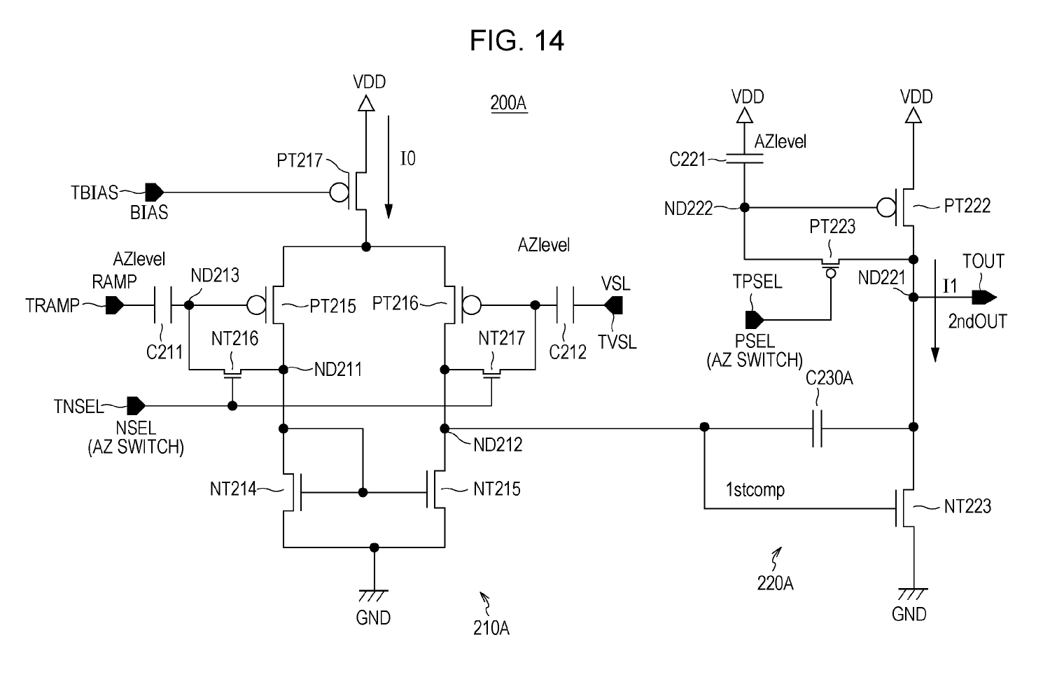

FIG. 14 is a circuit diagram illustrating a modification of the comparator in accordance with the present embodiment. The comparator 200A shown in FIG. 14 is configured such that the polarity of the transistors is the reverse of that of the comparator 200 shown in FIG. 4. For this reason, the connected power supply potential and ground potential are also reversed in the circuit. For the sake of simplicity, the reference numbers for the nodes and capacitors in FIG. 14 are identical to those used in FIG. 4.

In the first amp 210A, the differential comparator and current source are realized using PMOS transistors PT214 to PT217 instead of the NMOS transistors NT211 to NT213 shown in FIG. 4. Additionally, the source of the PMOS transistor PT217 that acts as the current source is connected to a power supply potential VDD.

Furthermore, the current mirror circuit is realized using NMOS transistors NT214 and NT215 instead of the PMOS transistors PT211 and PT212 shown in FIG. 4. Additionally, the sources of the NMOS transistors NT214 and NT215 are connected to the ground potential GND.

Furthermore, the AZ switches are realized using NMOS transistors NT216 and NT217 instead of the PMOS transistors PT213 and PT214 shown in FIG. 4. In this case, the second AZ signal NSEL is supplied to the gates of the NMOS transistors NT216 and NT217 in the first amp 210A.

In the second amp 220A, the input and amplification circuit is realized using an NMOS transistor NT223 instead of the PMOS transistor PT221 shown in FIG. 4. The source of the NMOS transistor NT223 is connected to the ground potential GND.

The transistor that forms the mirror circuit is realized using a PMOS transistor PT222 instead of the NMOS transistor NT221 shown in FIG. 4. The source of the PMOS transistor PT222 is connected to the power supply potential VDD. Meanwhile, the first electrode of the capacitor C221 is connected to the node ND222, which is itself connected to the PMOS transistor PT222, while the second electrode is connected to the power supply potential VDD.

Furthermore, the AZ switch is realized using a PMOS transistor PT223 instead of the NMOS transistor NT222 shown in FIG. 4. In this case, the first AZ signal PSEL is supplied to the gate of the PMOS transistor PT223 in the second amp 220A.

The first electrode of a capacitor C230A is connected to the gate (i.e., the input) of the NMOS transistor NT223, which acts as a common source amplifier. The second electrode is connected to the drain (i.e., the output) of the NMOS transistor NT223. The capacitor C230A exhibits the Miller effect, and is equivalent to connecting a gain-multiplied capacitor at the common source input.

If the gain of the NMOS transistor NT223 is taken to be A_{V2} and the capacitance of the capacitor C230A is taken to be C, then the capacitance seen at the output of the first amp 210A becomes multiplied by the gain according to {C*(1+A_{V2})}. For this reason, the capacitance of the capacitor C230A may be small. As a result, the passband of the comparator 200A can be significantly narrowed using a small capacitor.

The comparator 200A having the above configuration and shown in FIG. 14 is basically similar in operation to the comparator 200 shown in FIG. 4, but wherein the waveforms of the RAM, 1stcomp, and 2ndAMP signals in the timing chart shown in FIG. 12 are reversed. Thus, according to the comparator 200A shown in FIG. 14, advantages are obtained similar to those of the comparator 200 shown in FIG. 4.

As described in the foregoing, the present embodiment includes: a pixel unit 110 wherein a plurality of pixels that conduct photoelectric conversion are disposed in a matrix; and a pixel signal readout unit 150 (i.e., the ADC group) that reads out data from the pixel unit 110 on a per-row basis.

The ADC group 150 compares readout signal potentials disposed in accordance with column-parallel pixels to a reference voltage, and includes: a plurality of comparators 151 that output a determination signal based on the comparison result; and a plurality of counters 152 that count the comparing time of a corresponding comparator.

Each comparator 151 includes: a first amp 210, a second amp 220, connected to the first amp 210 in a cascading manner, that functions as an amplifier that increases the gain of the output of the first amp 210; and a capacitor C230 connected between the input and output of a common source amplifier in the second amp in order to exhibit the Miller effect.

Consequently, according to the present embodiment, the following advantages are obtained.

Since the passband of each comparator is highly constrained by using the Miller effect of a capacitor, both pixel noise and comparator noise can be reduced. Since the Miller effect is used to constrain the passband of the comparator, it is possible to reduce noise while keeping the inversion time of the comparator short. Since the inversion time is not worsened, the frame rate is not reduced.

Furthermore, since the Miller effect is used to constrain the passband of the comparator, the passband can be highly constrained with a small capacitor. Thus, circuit area and cost can be reduced in comparison to a technique of the related art while still realizing the same noise reduction effects.

A solid state image sensor having the above advantages is applicable for use as an imaging device in a digital or video camera.

### <6. Exemplary Configuration of a Camera System>

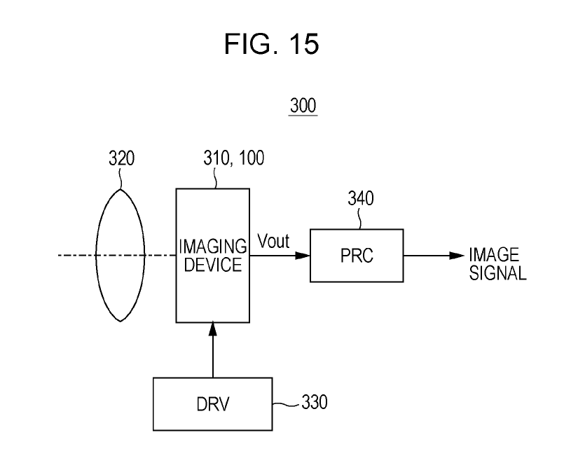

FIG. 15 illustrates an exemplary configuration of a camera system to which a solid state image sensor in accordance with an embodiment of the present invention has been applied. As shown in FIG. 15, the camera system 300 includes an imaging device 310, to which a CMOS image sensor (i.e., the solid state image sensor 100) in accordance with the present embodiment can be applied.

The camera system 300 also includes optics for guiding incident light (i.e., focusing a subject image) onto the pixel region of the imaging device 310. The optics may be, for example, a lens 320 that focuses incident light (i.e., image light) onto the imaging surface.

The camera system 300 also includes a driving circuit (DRV) 330 that drives the imaging device 310, as well as a signal processing circuit (PRC) 340 that processes output signals from the imaging device 310.

The driving circuit 330 includes a timing generator (not shown) that generates various timing signals, including start pulses and clock pulses for driving circuits within the imaging device 310. The driving circuit 330 drives the imaging device 310 using predetermined timing signals.

The signal processing circuit 340 performs predetermined signal processing with respect to output signals from the imaging device 310.

An image signal processed by the signal processing circuit 340 is recorded into a recording medium, such as memory. A hard copy may then be made of the image information recorded onto the recording medium by a printer or other apparatus. Alternatively, the image signal processed by the signal processing circuit 340 may be output as a motion image to a monitor made up of a liquid crystal display or similar apparatus.

Thus, as described above, the solid-state image sensor 100 described in the foregoing may be mounted onboard an imaging apparatus such as a digital still camera in the form of the imaging device 310, thereby realizing a high-precision camera.

The present application contains subject matter related to that disclosed in Japanese Priority Patent Application JP 2008-262974 filed in the Japan Patent Office on Oct. 9, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid state image sensor, comprising:
a pixel unit configured such that a plurality of pixels that conduct photoelectric conversion are disposed in a matrix; and
a pixel signal readout unit configured to read out the plurality of pixel signals from the pixel unit on a per-pixel basis;
wherein
the pixel signal readout unit includes
a plurality of comparators, disposed column-parallel with respect to the pixels, configured to compare a readout signal potential to a reference voltage, and output a determination signal based on the comparison result, and
a plurality of counters configured to count the comparing time of a corresponding comparator,
and wherein
each comparator includes
a first amp containing a differential amplifier configured to receive the reference voltage at the gate of a transistor, receive the readout signal at the gate of another transistor, and compare the reference voltage to the readout signal potential,
a second amp containing an amplifier configured to increase the gain of the output of the first amp, and output the result, and
a capacitor connected between the input and the output of the amplifier in the second amp in order to exhibit the Miller effect.

2. The solid-state image sensor according to claim 1, wherein the capacitor connected between the input and the output of the second amp multiplies the gain as seen from the output of the first amp according to {C*(1+A_{V2})}, where A_{V2} is the gain of the amplifier, and C is the capacitance of the capacitor.

3. The solid-state image sensor according to claim 1 or 2, wherein
the amplifier in the second amp is formed by a common source field effect transistor supplied with the output of the first amp at the gate thereof, and
the capacitor is connected between the gate and the drain of the common source field effect transistor.

4. The solid-state image sensor 100 according to claim 1, wherein
the first amp includes
the differential transistor configured to receive the reference voltage at the gate of a transistor, receive the readout signal at the gate of another transistor, and compare the reference voltage to the readout signal potential,
an auto-zero switch connected between the gate and the drain of the differential transistor in order to determine the working point in each column when initiating row operations, and
first and second capacitors, connected to each gate of the differential transistor, and configured to sample the auto-zero level.

5. The solid-state image sensor according to claim 4, wherein
the second amp includes
an auto-zero switch configured to determine the working point in each column when initiating row operations, and
a third capacitor configured to sample the auto-zero level.

6. The solid-state image sensor according to claim 5, wherein
the second amp includes
a first conductivity type field effect transistor configured to receive the output of the first amp at the gate thereof, and
a second conductivity type field effect transistor connected in series with the first conductivity type field effect transistor, having an auto-zero switch disposed between the gate and the drain thereof, and wherein the gate is connected to the third capacitor,
an output node is formed at the connection point between the first conductivity type field effect transistor and the second conductivity type field effect transistor, and wherein
the capacitor configured to exhibit the Miller effect is connected between the gate and the drain of the first conductivity type field effect transistor.

7. A camera system, comprising:
a solid-state image sensor; and
optics configured to focus a subject image onto the image sensor;
wherein
the solid-state image sensor includes
a pixel unit configured such that a plurality of pixels that conduct photoelectric conversion are disposed in a matrix, and
a pixel signal readout unit configured to read out the plurality of pixel signals from the pixel unit on a per-pixel basis,
the pixel signal readout unit includes
a plurality of comparators, disposed column-parallel with respect to the pixels, configured to compare a readout signal potential to a reference voltage, and output a determination signal based on the comparison result, and
a plurality of counters configured to count the comparing time of a corresponding comparator,
and wherein
each comparator includes
a first amp containing a differential amplifier configured to receive the reference voltage at the gate of a transistor, receive the readout signal at the gate of another transistor, and compare the reference voltage to the readout signal potential,
a second amp containing an amplifier configured to increase the gain of the output of the first amp, and output the result, and
a capacitor connected between the input and the output of the amplifier in the second amp in order to exhibit the Miller effect.
